(19) United States
(12) Patent Application Publication
(10) Pub. No.: US 2008/0106316 A1
(43) Pub. Date: May 8, 2008

(54) CLOCK GENERATOR, DATA DRIVER, CLOCK GENERATING METHOD FOR LIQUID CRYSTAL DISPLAY DEVICE

(76) Inventor: Jae Min HA, Gyeonggi-Do (KR)

Correspondence Address: MACPHERSON KWOK CHEN & HEID LLP, 2033 GATEWAY PLACE, SUITE 400, SAN JOSE, CA, 95110, US

(21) Appl. No.: 11/935,919

(22) Filed: Nov. 6, 2007

(30) Foreign Application Priority Data
Nov. 7, 2006 (KR) 10-2006-0109578

(51) Int. Cl. H03K 3/00

(52) U.S. Cl. 327/299

(57) ABSTRACT

A clock generator and data driver for a liquid crystal display device in which the clock generator includes a bias voltage supply receiving a power supply voltage and generating a bias voltage, an internal clock generator converting differential clock signals into an internal clock signal in response to the bias voltage, a bias line electrically connecting the bias voltage supply and the internal clock generator to supply the bias voltage to the internal clock generator, and a shield line shielding the bias line and receiving a voltage having a level identical with a level of the bias voltage.

### CROSS REFERENCE TO RELATED APPLICATIONS

This application claims priority of Korea Patent Application No. 2006-109578, filed Nov. 7, 2006, the entire disclosure of which is incorporated herein by reference.

### BACKGROUND OF THE INVENTION

1. Field of the Invention

The present invention relates to a liquid crystal display device and, more particularly, to a clock generator, a data driver, and a clock generating method for a liquid crystal display device.

2. Description of the Related Art

Typically, liquid crystal display (“LCD”) devices display images by using electric fields to control the light transmissivity characteristics of the liquid crystals. An LCD device is constructed such that a thin film transistor substrate and a color filter substrate having respective electrodes face each other with the liquid crystal disposed between the two substrates. The liquid crystal molecules are excited by the electric field generated when a voltage is applied across the substrates.

The LCD device includes an LCD panel having a plurality of liquid crystal cells formed at intersections of gate lines and data lines, a gate driver that outputs gate signals to the gate lines, a data driver that outputs data signals to the data lines, a timing controller that controls the gate driver and the data driver, and a power supply providing the driving voltage of the LCD panel.

In a conventional LCD device, however, a ripple in the power supply voltage supplied to the data driver delays the internal clock, resulting in an abnormal screen image being displayed on the LCD panel.

### SUMMARY OF THE INVENTION

According to one aspect of the present invention the ripple voltage problem is eliminated from a clock generator and a data driver by removing the effect of parasitic capacitance by applying a bias voltage to a shield line shielding the bias line of an interface receiver.

In one exemplary embodiment of the present invention, a clock generator for a liquid crystal display device includes a bias voltage supply receiving a power supply voltage and generating a bias voltage, an internal clock generator converting differential clock signals into an internal clock signal in response to the bias voltage, a bias line electrically connecting the bias voltage supply and the internal clock generator to supply the bias voltage to the internal clock generator, and a shield line shielding the bias line and receiving a voltage having a level identical with a level of the bias voltage.

In another exemplary embodiment of the present invention, a data driver for a liquid crystal display device includes a shift register receiving a data start signal and an internal clock signal and generating a sampling signal, an input register storing a data signal in response to the sampling signal, a storage register storing the data signal stored in the input register in response to a load signal, a digital-to-analog converter converting the data signal stored in the storage resister into an analog voltage using a gamma voltage, an output buffer outputting the analog voltage through a corresponding data line, and an interface receiver converting the differential clock signals into the internal clock signal, wherein the interface receiver includes a bias voltage supply receiving a power supply voltage and generating a bias voltage, an internal clock generator converting the differential clock signals into the internal clock signal in response to the bias voltage, a bias line electrically connecting the bias voltage supply and the internal clock generator to supply the bias voltage to the internal clock generator, and a shield line shielding the bias line and receiving a voltage having a level identical with a level of the bias voltage.

In a further exemplary embodiment of the present invention, a method of generating a clock includes generating a bias voltage by supplying a power supply voltage to a bias voltage supply, supplying a voltage having a level identical with a level of the bias voltage to a shield line shielding a bias line and supplying the bias voltage to an internal clock generator via the bias line, and generating an internal clock signal by converting a differential clock signal into the internal clock signal by the internal clock generator in response to the bias voltage.

### BRIEF DESCRIPTION OF THE DRAWINGS

The above and other features and advantages of the present invention will be more apparent from the following detailed description in conjunction with the accompanying drawings, in which:

FIG. 1 is a block diagram illustrating an LCD device according to an exemplary embodiment of the present invention;

FIG. 2 is a block diagram illustrating a data driver shown in FIG. 1;

FIG. 3 is a circuit diagram illustrating a clock generator of an RSDS receiver shown in FIG. 2 according to an exemplary embodiment of the present invention; and

FIG. 4 is a circuit diagram illustrating an internal clock generator shown in FIG. 3 according to another exemplary embodiment of the present invention.

### DETAILED DESCRIPTION

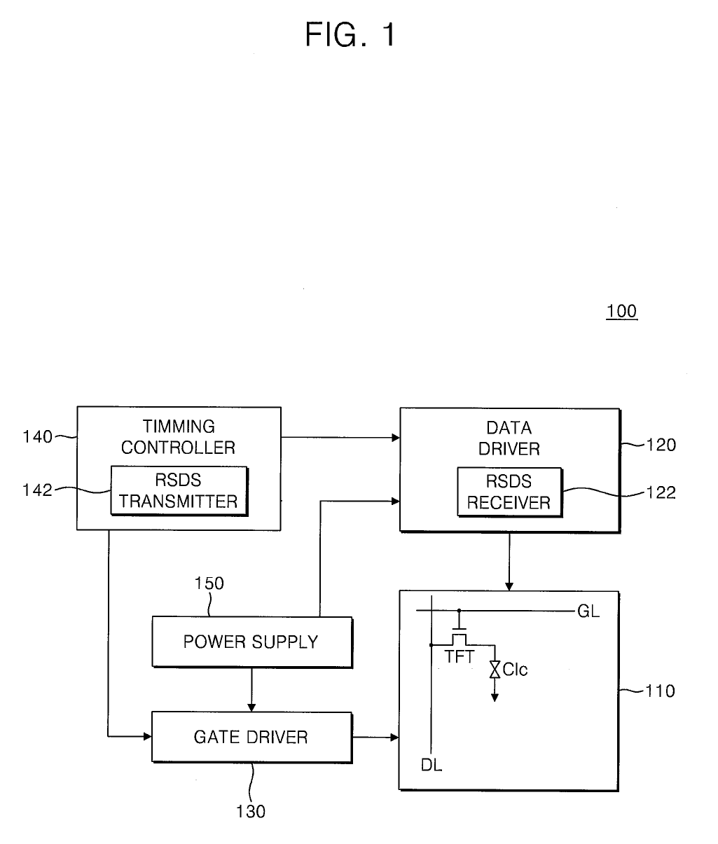

FIG. 1 is a block diagram illustrating an LCD device according to an exemplary embodiment of the present invention.

As shown in FIG. 1, the LCD device includes an LCD panel 110, a data driver 120, a gate driver 130, a timing controller 140, and a power supply 150.

The LCD panel 110 includes an upper substrate having a color filter, a lower substrate having a thin film transistor (“TFT”) array and facing the upper substrate, and liquid crystal filled between the upper and lower substrates. The lower substrate includes a plurality of liquid crystal cells Clc formed at intersections of a plurality of gate lines GL and a plurality of data lines DL and includes TFTs supplying data signals to the liquid crystal cells Clc in response to a gate driving signal. Each of the TFTs includes a gate electrode connected to the gate line GL, a source electrode connected to the data line DL, and a drain electrode electrically connected to a pixel electrode of each liquid crystal cell Clc.

The data driver 120 applies an analog voltage corresponding to the data signal to the TFTs driven by the gate driving. The data driver 120 receives a control signal and the data signal from the timing controller 140 and receives a driving voltage from the power supply 150. The driving voltage includes both a power supply voltage and a ground voltage. The data driver 120 includes a reduced swing differential signaling (“RSDS”) receiver 122 corresponding to an RSDS transmitter 142 of the timing controller 140.

RSDS is an interface method that can be used so that the data driver 120 can receive the control signal and data signal from the timing controller 140. In this embodiment, the interface method between the timing controller 140 and data driver 120 uses RSDS by way of example. However, the present invention is not limited thereto, and may be implemented with low voltage differential signaling (“LVDS”), mini LVDS, or point-to-point differential signaling (“PPDS”).

The gate driver 130 sequentially applies the gate driving signal to the gate lines GL to simultaneously turn ON the TFTs connected to the gate line. The gate driver 130 receives the control signal from the timing controller 140 and receives the driving voltage from the power supply 150.

The timing controller 140 converts external data signals into data signals capable of being processed in the data driver 120. And the timing controller 140 supplies control signals to the data driver 120 and the gate driver 130. The timing controller 140 includes the RSDS transmitter 142 corresponding to the RSDS receiver 122 of the data driver 120. The data signals applied to the data driver 120 are red (R), green (G), and blue (B) data signals and the control signals includes a differential clock signal, a horizontal synchronization signal, and a load control signal.

The power supply 150 supplies the driving voltage to the data driver 120 and the gate driver 130. The driving voltage supplied to the data driver 120 includes the power supply voltage, the ground voltage, and a gamma voltage.

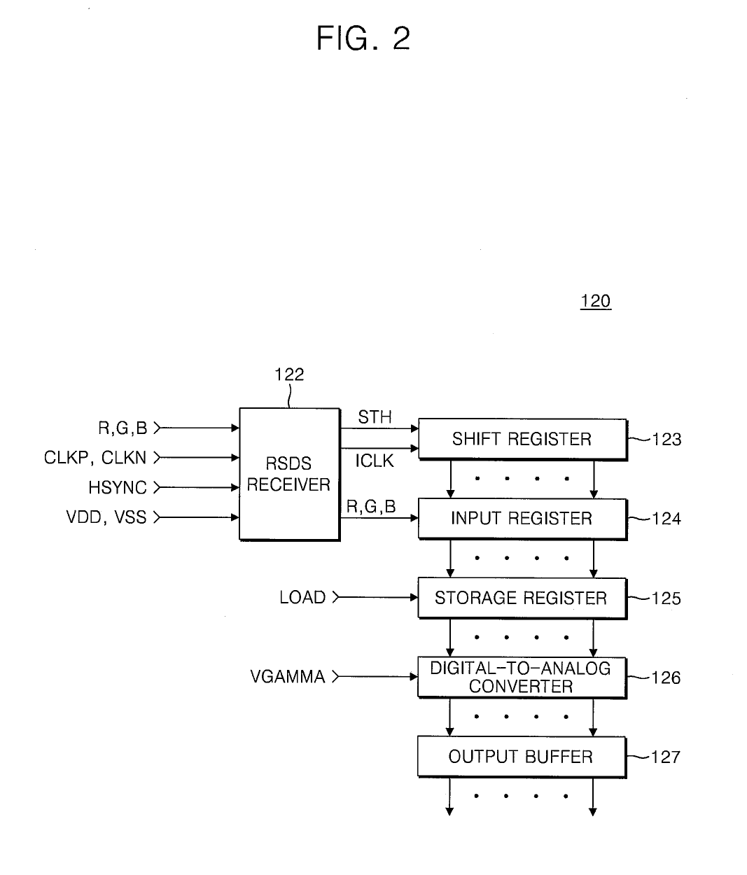

FIG. 2 is a block diagram illustrating the data driver 120 shown in FIG. 1. The data driver 120 includes a shift register 123, an input register 124, a storage register 125, a digital-to-analog converter 126, an output buffer 127, and the RSDS receiver 122.

The shift register 123 receives a horizontal start signal STH and an internal clock signal ICLK and generates a sampling signal to be supplied to the input register 124. The input register 124 sequentially stores the R, G, and B data signals in response to the sampling signal from the shift register 123. The storage register 125 stores data signals corresponding to one data line stored in the input register 124 in response to a load control signal LOAD from the timing controller 140. The data signals stored in the storage register 125 are converted into analog voltage signals by the digital-to-analog converter 126 in accordance with a gamma voltage VGAMMA from the timing controller 140 and then input to the output buffer 127. The output buffer 127 outputs the analog voltage signals through the corresponding data line.

The RSDS receiver 122 receives the R, G, and B data signals and the control signals including differential clock signals CLKP and CLKN and a horizontal synchronization signal HSYNC from the timing controller 140 and converts the R, G, and B data signals and the control signals into signals capable of being processed in the shift register 123 and the input register 124. The RSDS receiver 122 also receives a power supply voltage VDD and a ground voltage VSS from the power supply 150.

The RSDS receiver 122 includes a data signal conversion circuit for converting the R, G, and B data signals into signals capable of being processed in the input register 124, a control signal conversion circuit for converting the horizontal synchronization signal HSYNC into the horizontal start signal STH capable of being processed in the shift register 123, and a clock generator for converting the differential clock signals CLKP and CLKN into the internal clock signal ICLK.

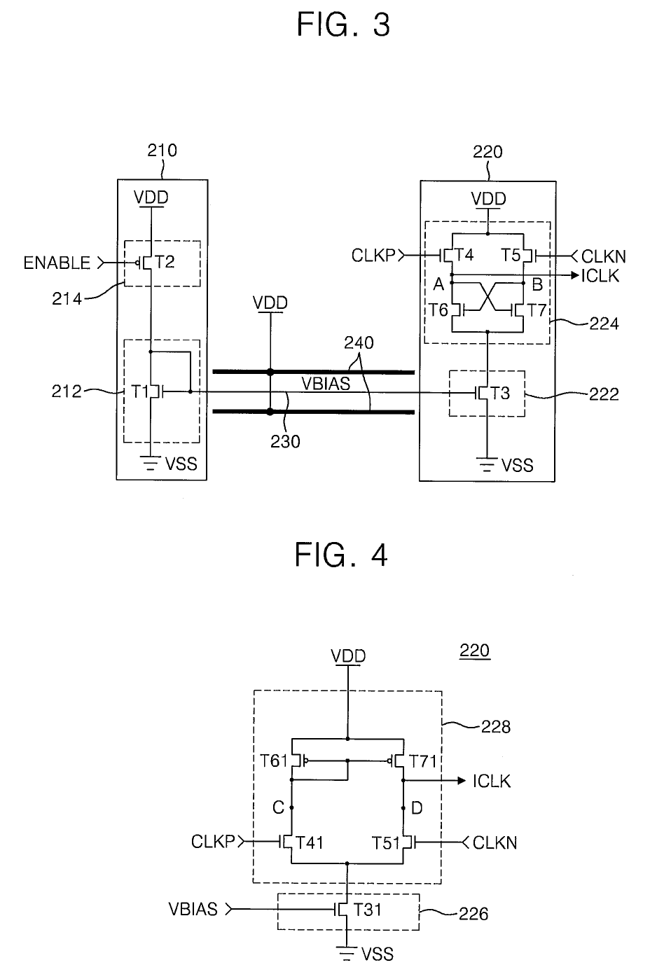

FIG. 3 is a circuit diagram illustrating the clock generator of the RSDS receiver 122 shown in FIG. 2.

The clock generator of the RSDS receiver 122 of FIG. 2 includes a bias voltage supply 210, an internal clock generator 220, a bias line 230, and a pair of shield lines 240.

The bias voltage supply 210 receives the power supply voltage VDD and supplies a bias voltage VBIAS to the internal clock generator 220. The bias voltage supply 210 includes a constant voltage generator 212 generating the bias voltage VBIAS and a pull-up part 214 applying the power supply voltage VDD to the constant voltage generator 212 in response to an enable signal ENABLE.

The constant voltage generator 212 is implemented with a first NMOS transistor T1 of a diode type. The NMOS transistor T1 has a gate electrode electrically connected to a bias line 230 to output the bias voltage VBIAS, a source electrode connected to the ground voltage VSS, and a drain electrode commonly electrically connected to the bias line 230 and the gate electrode. The pull-up part 214 is implemented with a first PMOS transistor T2 having a drain electrode connected to the drain electrode of the first NMOS transistor T1, a gate electrode connected to the enable signal ENABLE, and a source electrode connected to the power supply voltage VDD.

The internal clock generator 220 converts the differential clock signals CLKP and CLKN input from the timing controller 140 into the internal clock signal ICLK in response to the bias voltage VBIAS applied through the bias line 230. More specifically, the internal clock generator 220 includes a differential amplifier 224 converting the differential clock signals CLKP and CLKN into the internal clock signal ICKL in response to a constant current from the power supply voltage VDD, and a pull-down part 222 connecting the differential amplifier 224 to a ground voltage VSS.

The pull-down part 222 is implemented with a second NMOS transistor T3 having a source electrode connected to the ground voltage VDD, a gate electrode connected to the bias voltage VBIAS through the bias line 230, and a drain electrode connected to the differential amplifier 224.

The differential amplifier 224 includes third and fourth NMOS transistors T4 and T5 connected respectively to the differential clock signals CLKP and CLKN, and fifth and sixth NMOS transistors T6 and T7 of which drain electrodes and gate electrodes are cross-coupled to each other. The third and fourth NMOS transistors T4 and T5 include respective drain electrodes connected commonly to the power supply voltage VDD, and gate electrodes connected respectively to the differential clock signals CLKP and CLKN, and source electrodes coupled respectively to the drain electrodes of the fifth and sixth NMOS transistors T6 and T7. It is preferable that the channel widths and lengths of the third and fourth NMOS transistors T4 and T5 are identical. The fifth and sixth transistor T6 and T7 have drain electrodes connected respectively to the source electrodes of the third and forth NMOS transistors T4 and T5, gate electrodes cross-coupled to their drain electrodes, and source electrodes connected to the drain electrode of the second NMOS transistor T3 of the pull-down part 222. A node ‘A’ to which the source electrode of the third NMOS transistor T4 and the drain electrode of the fifth NMOS transistor T6 are commonly connected serves as an output node of the differential amplifier 224.

The bias line 230 electrically connects the bias voltage supply 210 and the internal clock generator 220 to each other to supply the bias voltage VBIAS generated from the bias voltage supply 210 to the internal clock generator 220. In more detail, the bias line 230 connects an output node of the bias voltage supply 210, i.e. the gate electrode of the first NMOS transistor T1 of the constant voltage generator 212 to an input node of the internal clock generator 220, i.e. the gate electrode of the third NMOS transistor T3 of the pull-down part 222.

The shield lines 240 are spaced by a predetermined distance to stabilize the bias voltage VBIAS applied to the bias line 230. The two shield lines 240 may be shielded from the bias line 230 by being arranged at both sides with the bias line 230 disposed therebetween on an identical plane of a printed circuit board on which the bias line 230 is formed. When the printed circuit board on which the bias line 230 is formed is implemented with multiple layers, the two shield lines 240 may be shielded from the bias line 230 by being arranged at upper and lower sides of the bias line 230. The shield lines 240 are arranged in parallel with the bias line 230 and the number of shield lines may be one or more. The shield lines 240 are preferably induced by the bias voltage VBIAS applied to the bias line 230. In this embodiment, the bias voltage VBIAS is the power supply voltage VDD so that the power supply voltage VDD is applied to the shield lines 240.

An operation of the above structured clock generator of the RSDS receiver is described hereinafter.

First, an operation of the bias voltage supply 210 is explained. When the enable signal ENABLE of a low level is applied to the bias voltage supply 210, the first PMOS transistor T2 of the pull-up part 214 is turned ON and supplies the power supply voltage VDD to the constant voltage generator 212. Since the constant voltage generator 212 has a diode structure in which the drain and gate electrodes of the first NMOS transistor T1 are commonly connected to the power supply voltage VDD, the bias voltage VBIAS supplied from the bias voltage supply 210 becomes a level of the power supply voltage VDD.

When the enable signal ENABLE of a high level is applied to the bias voltage supply 210, the first PMOS transistor T2 of the pull-up part 214 is turned OFF. Then the connection to the power supply voltage VDD is released and current flows through the source electrode of the constant voltage generator 212 connected to the ground voltage VSS, thereby lowering a voltage level of the drain and gate electrodes of the constant voltage generator 212.

The enable signal ENABLE may be a low level voltage, for example, the ground voltage VSS. When the enable signal ENABLE is a low level voltage, the bias voltage supply 212 applies the power supply voltage VDD to the internal clock generator 220 as the bias voltage VBIAS.

Next, the operation of the internal clock generator 220 is explained. When the bias voltage VBIAS is applied from the bias voltage supply 210, the pull-down part 222 is turned ON to connect the differential amplifier 224 to the ground voltage VSS. The ground voltage VSS is then supplied to the source electrodes of the fifth and sixth NMOS transistors T6 and T7.

When the differential clock signal CLKP applied to the internal clock generator 220 is a high level, the third NMOS transistor T4 is turned ON to raise an electric potential at the node A. The sixth NMOS transistor T7 of which gate is connected to the node A is turned ON to connect the node B to the ground voltage. At this time, the differential clock signal CLKN has a low level to turn OFF the fourth NMOS transistor T5 for protecting the rise of the electric potential at the node B. Accordingly, the electric potential at the node B maintains the ground voltage level VSS and the fifth NMOS transistor T6 of which gate is connected to the node B is turned OFF to maintain the electric potential at the node A. That is, when the differential clock signal CLKP is a high level, the internal clock generator 220 outputs the internal clock signal ICLK of a high level through the output node connected to the node A.

When the differential clock signal CLKN applied to the internal clock generator 220 is a high level, the fourth NMOS transistor T5 is turned ON to raise the electric potential at node B. The fifth NMOS transistor T6 of which gate is connected to the node B is turned ON to ground the node A. At this time, the differential clock signal CLKP of a low level is applied to the clock generator 220 to turn OFF the third NMOS transistor T4 for protecting the rise of the electric potential at the node A. Accordingly, the electric potential at the node A maintains the ground voltage level VSS and the sixth NMOS transistor T7 of which gate is connected to the node A is turned OFF to maintain the electric potential at the node B. That is, when the differential clock signal CLKP is a low level, the internal clock generator 220 outputs the internal clock signal ICLK of a low level through the output node connected to the node A. In the above described manner, the internal clock generator 220 generates the internal clock signal ICLK according to the differential clock signals CLKP and CLKN.

The relationship between the bias line 230 and the shield lines 240 is described especially when a ripple occurs on the power supply voltage VDD. In this embodiment, a voltage of the same level, i.e. the bias voltage VBIAS, is applied to the shield lines 240 and the bias line 230. Accordingly, even when a ripple voltage is superimposed on the power supply voltage VDD, the bias voltage supply 210 can stably supply the bias voltage VBIAS to the internal clock generator 220.

More specifically, when a voltage ripple is superimposed on the power supply voltage VDD supplied through the bias line 230, the ripple propagates to the bias voltage VBIAS and occurs on the power supply voltage VDD applied to the internal clock generator 220, thereby having no effect on the internal clock generator 220. Also, since the voltages induced in the bias line 230 and the shield lines 240 have substantially the same level, a parasite capacitance formed between the bias line 230 and the shield lines 240 has no effect on a ripple voltage.

However, when the level of a voltage applied to the shield lines 240 is different from the level of the bias voltage VBIAS induced to the bias line 230, if the voltage ripple drops, the bias voltage VBIAS fluctuates because of the parasitic capacitance between the bias line 230 and the shield lines 240. Therefore, the pull-down part 222 of the internal clock generator 220 fails to supply a regulated current to the differential amplifier 224 and the internal clock generator 220 delays the generation of the internal clock ICLK.

FIG. 4 is a circuit diagram illustrating another exemplary embodiment of the internal clock generator 220 shown in FIG. 3 according to the present invention. As shown in FIG. 4, the internal clock generator 220 of the RSDS receiver includes a current mirror type differential amplifier 228 and a pull-down part 226 which is grounded.

The differential amplifier 228 includes first and second current mirror type PMOS transistors T61 and T71, and first and second NMOS transistors T41 and T51 inputting the differential clock signals CLKP and CLKN. Gates of the PMOS transistors T61 and T71 are commonly connected to any one of their drains. The first and second PMOS transistors T61 and T71 have respective sources connected to the power supply voltage VDD, respective gates connected commonly to the drain of the first PMOS transistor T61, and respective drains connected respectively to drains of the NMOS transistors T41 and T51. The first and second NMOS transistors T41 and T51 have respective drains respectively connected to the drains of the PMOS transistors T61 and T71, respective gates connected respectively to the differential clock signals CLKP and CLKN, and respective sources connected to the pull-down part 226. It is preferable that the channel lengths and widths of the first and second NMOS transistors T41 and T51 are identical with each other.

The pull-down part 226 includes a third NMOS transistor T31 having a drain connected commonly to the sources of the first and second NMOS transistors T41 and T51, a gate connected to the bias voltage VBIAS, and a source connected to a ground voltage VSS. A node D connecting the drain of the second PMOS transistor T71 and the drain of the second NMOS transistor T51 becomes an output node of the differential amplifier 228.

The operation of the above-structured internal clock generator 220 of the RSDS receiver is described hereinafter. When the bias voltage VBIAS of high level is supplied from the bias voltage supply 210, the third NMOS transistor T31 of the pull-down part 226 is turned ON to connect the differential amplifier 228 to a ground voltage VSS. When the differential clock signal CLKP of a high level is applied to the internal clock generator 228, the first NMOS transistor 41 is turned ON to ground a node C through the third NMOS transistor T31. The node C has an electrical potential of the ground voltage level VSS and the second PMOS transistor T71 of which gate is connected to the node C is turned ON to raise the electric potential at the node D. At this time, the differential clock signal CLKN of a low level is applied to turn OFF the second NMOS transistor T51 for protecting the rise of the electric potential at the node D. That is, when the differential clock signal CLKP is a high level, the internal clock generator 220 outputs the internal clock signal ICLK of a high level through the output node connected to the node D.

When the differential clock signal CLKN of a high level is applied to the internal clock generator 220, the second NMOS transistor T51 is turned ON and the node D is grounded through the third NMOS transistor T31. The electric potential at the node D has the ground voltage level VSS. At this time, the differential clock signal CLKP having a low level is applied to turn OFF the first NMOS transistor T41, thereby maintaining the electric potential at the node C. That is, when the differential clock signal CLKP is at a low level, the internal clock generator 220 outputs the internal clock signal ICLK of a low level through the output node connected to the node D.

In this manner, the internal clock signal generator 220 generates the internal clock signal ICLK in accordance with the differential clock signals CLKP and CLKN.

As described above, the clock generator and the data driver using the clock generator according to the present invention are provided with a shield line induced with a voltage having a level identical with a level of a bias voltage on the bias line, thereby removing the effect of parasitic capacitance between the bias line and the shield line.

Accordingly, even when a voltage ripple is superimposed on the power supply voltage, the bias voltage can be stably supplied to the internal clock generator, so that it is possible to prevent the data driver from malfunctioning because of the voltage ripple.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A clock generator for a liquid crystal display device that overcomes the effect of a ripple voltage in a power supply, comprising:
a bias voltage supply generating a bias voltage from the power supply;
an internal clock generator converting differential clock signals into an internal clock signal in response to the bias voltage;
a bias line electrically connecting the bias voltage supply and the internal clock generator to supply the bias voltage to the internal clock generator; and
a shield line shielding the bias line and receiving a voltage having a level which is substantially the same as a level of the bias voltage.

2. The clock generator of claim 1, wherein the shield line parallels the bias line spaced at a predetermined distance therefrom.

3. The clock generator of claim 2, wherein the bias voltage supply comprises:
a constant voltage generator receiving the power supply voltage and generating the bias voltage; and
a pull-up part applying a power supply voltage to the constant voltage generator in response to an enable signal.

4. The clock generator of claim 3, wherein the pull-up part receives a ground voltage as the enable signal.

5. The clock generator of claim 2, wherein the internal clock generator comprises:
a differential amplifier converting the differential clock signals into the internal clock signal; and
a pull-down part connecting a ground voltage to the differential amplifier in response to the bias voltage to enable the differential amplifier.

6. The clock generator of claim 5, wherein the differential amplifier comprises a pair of MOS transistors of an identical channel width and length cross-coupled to each other.

7. The clock generator of claim 5, wherein the differential amplifier comprises a first MOS transistor having a diode connection and a second MOS transistor coupled to the first MOS transistor in a current mirror type.

8. The clock generator of claim 1, wherein the number of bias lines is two or more.

9. A data driver for a liquid crystal display, comprising:
a shift register receiving a data start signal and an internal clock signal and generating a sampling signal;
an input register generating a data signal in response to the sampling signal;
a storage register storing the data signal stored in the input register in response to a load signal;
a digital-to-analog converter converting the data signal stored in the storage register into an analog voltage using a gamma voltage;
an output buffer outputting the analog voltage through a corresponding data line; and
an interface receiver converting differential clock signals into the internal clock signal,
wherein the interface receiver comprises a bias voltage supply receiving a power supply voltage and generating a bias voltage, an internal clock generator converting the differential clock signals into the internal clock signal in response to the bias voltage, a bias line electrically connecting the bias voltage supply and the internal clock generator to supply the bias voltage to the internal clock generator, and a shield line shielding the bias line and receiving a voltage having a level which is substantially the same as a level of the bias voltage.

10. The data driver of claim 9, wherein shield line is arranged in parallel with the bias line spaced by a predetermined distance.

11. The data driver of claim 10, wherein the bias voltage supply comprises:
a constant voltage generator receiving the power supply voltage and generating the bias voltage; and
a pull-up part supplying a power supply voltage to the constant voltage generator in response to an enable signal.

12. The data driver of claim 11, wherein the pull-up part receives a ground voltage as the enable signal.

13. The data driver of claim 10, wherein the internal clock generator comprises:
a differential amplifier converting the differential clock signals into the internal clock signal according to a constant current; and
a pull-down part connecting a ground voltage to the differential amplifier in response to the bias voltage to enable the differential amplifier.

14. The data driver of claim 13, wherein the differential amplifier comprises a pair of MOS transistors of an identical channel width and length cross-coupled to each other.

15. The data driver of claim 13, wherein the differential amplifier comprises a first MOS transistor having a diode connection and a second MOS transistor coupled to the first MOS transistor in a current mirror type.

16. A method of generating a clock, comprising:
generating a bias voltage by supplying a power supply voltage to a bias voltage supply;
supplying a voltage having a level identical with a level of the bias voltage to a shield line shielding a bias line and supplying the bias voltage to an internal clock generator via the bias line; and
generating an internal clock signal by converting a differential clock signal into the internal clock signal by the internal clock generator in response to the bias voltage.

17. The method of claim 16, wherein the generating a bias voltage further comprises:
supplying a power supply voltage to a constant voltage generator by supplying an enable signal to a pull-up part; and
generating the power supply voltage supplied to the constant voltage generator as the bias voltage.

18. The method of claim 17, wherein the enable signal is a low level voltage to supply the power supply voltage to the constant voltage generator.

19. The method of claim 17, wherein the enable signal is a high level voltage to cut off the power supply voltage from being supplied to the constant voltage generator so that the bias voltage is lowered to a ground voltage.

20. The method of claim 16, wherein the generating an internal clock signal enables the internal clock generator by connecting a ground voltage to the internal clock generator in response to the bias voltage.
